(19) United States
(12) Patent Application Publication
(10) Pub. No.: US 2023/0163023 A1
(43) Pub. Date: May 25, 2023

(54) METHOD OF FABRICATING SEMICONDUCTOR DEVICE INCLUDING TWO-DIMENSIONAL MATERIAL LAYER DEFINING AIR-GAP, AND SEMICONDUCTOR DEVICE

(71) Applicant: SAMSUNG ELECTRONICS CO., LTD., Suwon-si, Gyeonggi-do (KR)

(72) Inventors: Sungjoo AN, Yongin-si (KR); Jungsoo YOON, Hwaseong-si (KR); Soyoung LEE, Yongin-si (KR); Keunwook SHIN, Yongin-si (KR)

(21) Appl. No.: 18/054,970

(22) Filed: Nov. 14, 2022

(30) Foreign Application Priority Data
Nov. 22, 2021 (KR) 10-2021-0161408

(51) Int. Cl. H01L 21/764; H01L 21/768; H01L 27/11556; H01L 27/11582

(52) U.S. Cl. CPC H01L 21/764; H01L 21/7682; H01L 27/11556; H01L 27/11582

(57) ABSTRACT

A method of fabricating a semiconductor device including a two-dimensional material layer defining an air-gap, and the semiconductor device therefrom are provided. The method of fabricating a semiconductor device, includes forming a structure on a substrate, wherein the structure has an opening; loading the substrate into a process chamber; forming at least one two-dimensional material layer on an upper surface of the structure so as to overlie the opening and form an air-gap, wherein an upper portion of the air-gap is defined by the at least one two-dimensional material layer; and unloading the substrate from the process chamber.

### CROSS-REFERENCE TO RELATED APPLICATION(S)

This application claims benefit of priority to Korean Patent Application No. 10-2021-0161408 filed on Nov. 22, 2021 in the Korean Intellectual Property Office, the disclosure of which is incorporated herein by reference in its entirety.

### BACKGROUND

The present inventive concept relates to methods of fabricating semiconductor devices.

There is increased demand for semiconductor devices with enhanced functionality. In order to meet performance and price requirements of consumers, the degree of integration and miniaturization of semiconductor elements has increased. Unfortunately, this may cause RC delay and hinder electrical signal transmission speeds.

### SUMMARY

Aspects of the present inventive concept include semiconductor devices including a two-dimensional material layer defining an air-gap, and methods of fabricating same.

According to an aspect of the present inventive concept, a method of fabricating a semiconductor device, includes forming a structure on a substrate, wherein the structure includes an opening; loading the substrate into a process chamber; forming at least one two-dimensional material layer on an upper surface of the structure so as to overlie the opening and form an air-gap, wherein an upper portion of the air-gap is defined by the at least one two-dimensional material layer; and unloading the substrate from the process chamber.

According to an aspect of the present inventive concept, a method of fabricating a semiconductor device, includes forming a structure on a substrate, wherein the structure includes an opening; and forming at least one two-dimensional material layer on an upper surface of the structure so as to overlie the opening and form an air-gap.

According to an aspect of the present inventive concept, a method of fabricating a semiconductor device, includes forming a structure on a substrate, wherein the structure includes an opening; and forming a non-conductive material layer using at least one two-dimensional material layer, wherein the non-conductive material layer is on an upper surface of the structure so as to overlie the opening and form an air-gap, and wherein an upper portion of the air-gap is defined by the non-conductive material layer.

According to an aspect of the present inventive concept, a semiconductor device includes a structure on a substrate, the structure having an opening; and at least one two-dimensional material layer on an upper surface of the structure so as to overlie the opening and form an air-gap.

According to an aspect of the present inventive concept, a semiconductor device includes a structure on a substrate, the structure having an opening; and a non-conductive material layer on an upper surface of the structure and that overlies the opening and forms an air-gap, wherein the non-conductive material layer comprises a material formed by amorphizing two-dimensional material layers grown in transverse and longitudinal directions, or an oxide of a two-dimensional material formed by oxidizing the two-dimensional material layers grown along the transverse and longitudinal directions.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1 to 5 illustrate operations for fabricating semiconductor devices according to an embodiment of the present inventive concept.

FIGS. 6 and 7A to 7D illustrate operations for fabricating semiconductor devices according to an embodiment of the present inventive concept.

FIG. 8 is a flowchart illustrating operations for fabricating semiconductor devices according to an embodiment of the present inventive concept.

FIG. 9 is a graph illustrating a result of analyzing a two-dimensional material layer by Raman spectroscopy.

FIG. 10 is a cross-sectional view of a semiconductor device fabricated according to an embodiment of the present inventive concept.

FIG. 11 is a cross-sectional view of a semiconductor device fabricated according to an embodiment of the present inventive concept.

FIGS. 12 and 13 illustrate operations for fabricating semiconductor devices according to an embodiment of the present inventive concept and a semiconductor device fabricated according to the operations.

FIG. 14 is a flowchart illustrating operations for fabricating semiconductor devices according to an embodiment of the present inventive concept.

FIG. 15 is a flowchart illustrating operations for fabricating semiconductor devices according to an embodiment of the present inventive concept.

FIG. 16 is a flowchart illustrating methods of fabricating semiconductor devices according to an embodiment of the present inventive concept.

FIG. 17 is a flowchart illustrating operations for fabricating semiconductor devices according to an embodiment of the present inventive concept.

FIGS. 18A to 18C are cross-sectional views illustrating a method of fabricating a semiconductor device according to embodiments of the present inventive concept and the semiconductor device fabricated according to the method.

FIGS. 19A to 19D are cross-sectional views illustrating a method of fabricating a semiconductor device fabricated according to embodiments of the present inventive concept and the semiconductor device fabricated according to the method.

### DETAILED DESCRIPTION

Hereinafter, terms such as “upper,” “intermediate,” and “lower” may be replaced with other terms, for example, “first,” “second,” and “third” to describe components of the present specification. The terms such as “first,” “second,” and “third” may be used to describe various components, but the components may not be restricted by the terms, and “first component” may be referred to as “second component.”

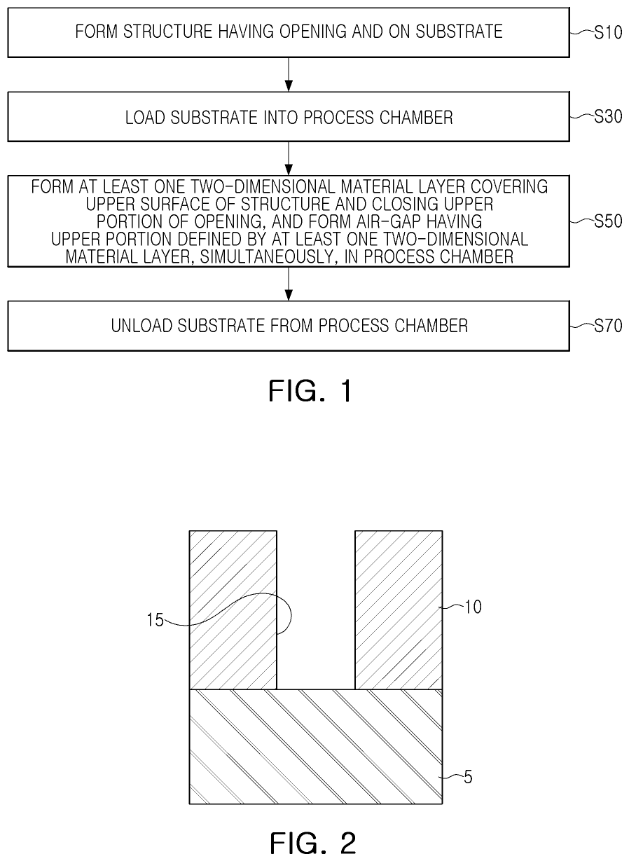

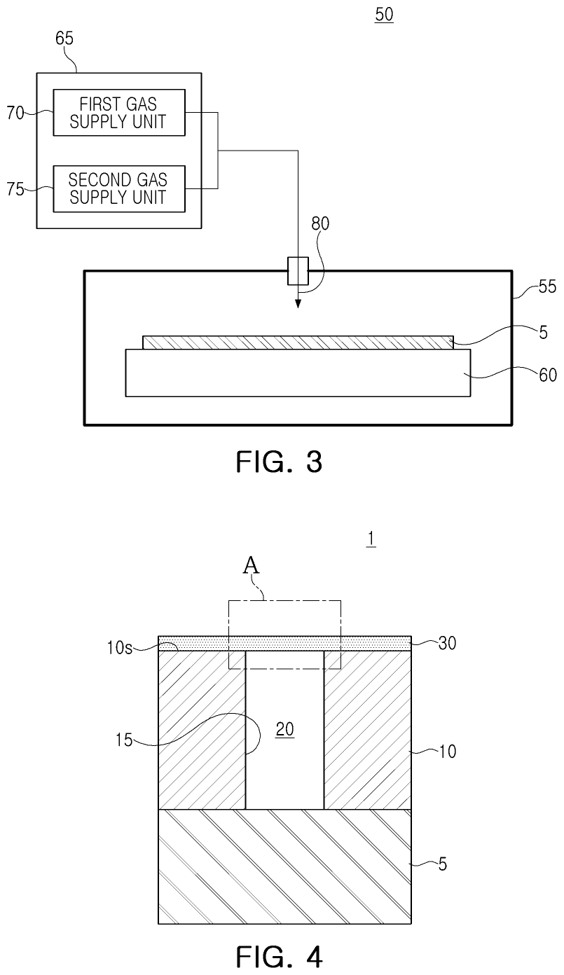

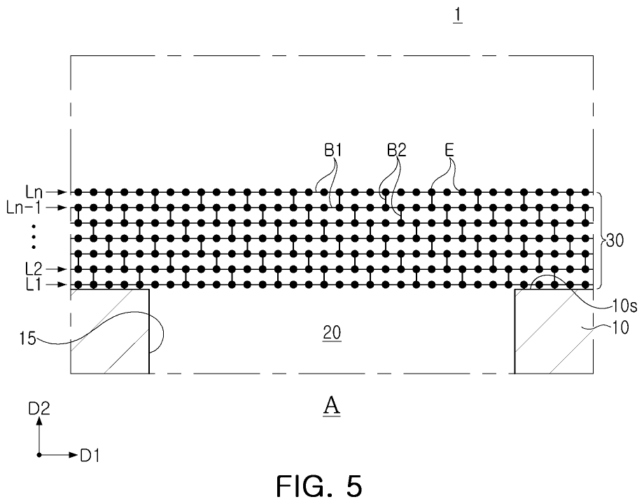

A method of fabricating a semiconductor device according to an embodiment of the present inventive concept and the semiconductor device fabricated according to the method will be described with reference to FIGS. 1 to 5. FIGS. 1 to 5 are views illustrating a method of fabricating a semiconductor device according to an embodiment of the present inventive concept and the semiconductor device fabricated according to the method. In FIGS. 1 to 5, FIG. 1 is a flowchart illustrating a method of fabricating a semiconductor device according to an embodiment of the present inventive concept, FIGS. 2 and 4 are cross-sectional views illustrating a method of fabricating a semiconductor device according to an embodiment of the present inventive concept, FIG. 3 illustrates a substrate processing apparatus including a process chamber for fabricating a semiconductor device according to an embodiment of the present inventive concept, and FIG. 5 illustrates an enlarged view of portion ‘A’ of FIG. 4, and that shows bonds of elements of a two-dimensional material in a semiconductor device according to an embodiment of the present inventive concept.

Referring to FIGS. 1 to 5, a structure 10 having an opening 15 may be formed on a substrate 5 (S10). The substrate 5 may be a semiconductor substrate, or a substrate on which a semiconductor integrated circuit is formed. For example, in the substrate 5, the semiconductor substrate may include a semiconductor material, such as a group IV semiconductor, a group III-V compound semiconductor, or a group II-VI compound semiconductor. For example, the group IV semiconductor may include silicon, germanium, or silicon-germanium. In the substrate 5, the semiconductor substrate may be provided as a bulk wafer, an epitaxial layer, a silicon-on-insulator (SOI) layer, a semiconductor-on-insulator (SeOI) layer, or the like.

In the substrate 5, the semiconductor integrated circuit may include a MOSFET transistor having a two-dimensional channel, a FinFET transistor having a three-dimensional channel, a multi bridge channel FET (MBCFET™) transistor, and a Gate-All-Around type field effect transistor.

In an example, the structure 10 may include active regions. For example, the structure 10 may include active regions formed while etching the substrate 5, and the opening 15 may be formed between the active regions.

In another example, the structure 10 may include wirings. For example, the structure 10 may be conductive wirings for electrically connecting the semiconductor integrated circuit, and the opening 15 may be formed between the conductive wirings. The wirings may be interconnection lines or conductive lines. The structure 10 may be referred to as wirings, interconnection lines, or conductive lines.

In another example, the structure 10 may be contact plugs or vias electrically connecting conductive patterns located on different height levels. The opening 15 may be formed between the contact plugs.

In another example, the structure 10 may be a conductive line and a contact plug, including portions located on substantially the same level, and the opening 15 of the structure 10 may be formed between the conductive line and the contact plug of the structure 10.

A width of the opening 15 may be about 1 nm to about 1 μm.

The width of the opening 15 may be about 1 nm to about 500 nm.

The substrate 5 may be loaded into a process chamber 55 (S30). The substrate 5 may be a substrate on which the structure 10 having the opening 15 is formed. The substrate 5 may be loaded onto a substrate support 60 in the process chamber 55.

The process chamber 55 may be a process chamber of a substrate processing apparatus 50 capable of forming a two-dimensional material layer. The substrate processing apparatus 50 may include a substrate support 60 capable of supporting the substrate 5 in the process chamber 55, and a gas supply device 65 capable of supplying a process gas 80 to the process chamber 55. The gas supply device 65 may include a first gas supply unit 70 and a second gas supply unit 75. The gas supply device 65 may be a device capable of supplying a gas for forming the two-dimensional material layer. For example, when the two-dimensional material layer may be a two-dimensional material layer such as graphene or the like, the first gas supply unit 70 may supply a precursor for providing an element of the two-dimensional material, and the second gas supply unit 75 may supply a mixed gas. The mixed gas may be an activation gas. For example, the first gas supply unit 70 may supply a precursor such as CₓH_{y}, for example, CH₄, C₂H₂, or the like into the process chamber 55, and the second gas supply unit 75 may supply a gas including at least one of H₂, N₂, or Ar into the process chamber 55.

In the process chamber 55, at least one two-dimensional material layer 30 covering an upper surface 10s of the structure 10 and closing an upper portion of the opening 15 (i.e., overlying the opening 15) may be formed, and an air-gap 20 having an upper portion defined by the at least one two-dimensional material layer 30 may be formed, simultaneously (S50).

The formation of the at least one two-dimensional material layer 30 in the process chamber 55 may include performing at a process temperature of about 100° C. to about 1500° C.

A thickness of the at least one two-dimensional material layer 30 may be about 3 Å to about 100 Å.

The at least one two-dimensional material layer 30 may be conductive.

In an example, the at least one two-dimensional material layer 30 may be formed as one two-dimensional material layer.

In another example, the at least one two-dimensional material layer 30 may be formed as a plurality of two-dimensional material layers (L1, L2, . . . , Ln−1, and Ln of FIG. 5), stacked in sequence.

When the at least one two-dimensional material layer 30 is formed as a plurality of two-dimensional material layers (L1-Ln of FIG. 5), the plurality of two-dimensional material layers (L1-Ln of FIG. 5) may be formed by sequentially stacking n two-dimensional material layers. In this case, n is a natural number of 2 or more and 30 or less.

When the at least one two-dimensional material layer 30 is formed as a plurality of two-dimensional material layers (L1-Ln of FIG. 5), the formation of the plurality of two-dimensional material layers (L1-Ln in FIG. 5) may include forming a two-dimensional material by growing the two-dimensional material in a transverse direction D1 and a longitudinal direction D2 on an upper surface 10s of the structure 10. In this case, a growth rate of the two-dimensional material in the transverse direction D1 may be higher than a growth rate of the two-dimensional material in the longitudinal direction D2. A growth rate of the two-dimensional material in the transverse direction D1 may be about 2 to about 100 times higher than a growth rate of the two-dimensional material in the longitudinal direction D2. The air-gap 20 may be formed by closing the upper portion of the opening 15 while growing the two-dimensional material in the transverse direction D1 on the upper surface 10s of the structure 10.

The transverse direction D1 may be a direction, substantially parallel to the upper surface 10s of the structure 10, and the longitudinal direction D2 may be a direction, substantially perpendicular to the upper surface 10s of the structure 10.

The plurality of two-dimensional material layers (L1-Ln in FIG. 5) may be formed by growing two-dimensional material elements (E in FIG. 5) in the transverse direction D1 while having a first bond B1 in the transverse direction D1, and growing the two-dimensional material elements E in the longitudinal direction D2 while having a second bond B2 in the longitudinal direction D2.

Each of the plurality of two-dimensional material layers (L1-Ln of FIG. 5) may be a carbon material layer. The carbon material layer may be graphene.

When the plurality of two-dimensional material layers (L1-Ln in FIG. 5) are formed as a carbon material layer having a carbon-carbon bond, the two-dimensional material elements E may be carbon, and the first bond B1 may be an SP2 bond, and the second bond B2 may be an SP3 bond.

The number of the first bonds B1 may be about 50% or more of the number of total bonds of the plurality of two-dimensional material layers (L1-Ln of FIG. 5).

In an embodiment, the two-dimensional material layer L of the at least one two-dimensional material layer 30 is not limited to a carbon material layer. For example, in the at least one two-dimensional material layer 30, the two-dimensional material layer L may include at least one of a transition metal dichalcogenide (TMD) material layer, a black phosphorous material layer, or a hexagonal boron-nitride (hBN) material layer.

The TMD material layer may include a first element, at least one of Mo or W, and a second element, at least one of S, Se, or Te. For example, the TMD material layer may include at least one of WS₂, WSe₂, or MoS₂.

The substrate 5 may be unloaded from the process chamber 55 (S70). The substrate 5 may be a substrate in which the at least one two-dimensional material layer 30 and the air-gap 20 are formed. Therefore, the semiconductor device 1 including the at least one two-dimensional material layer 30 defining the air-gap 20 may be formed.

The semiconductor device 1 fabricated by the method of fabricating a semiconductor device, described above, may include the structure 10 having the opening 15, the at least one two-dimensional material layer 30 covering the upper surface 10s of the structure 10 and closing the upper portion of the opening 15, and the air-gap 20 in the opening 15, defining an upper portion, by the at least one two-dimensional material layer 30.

The at least one two-dimensional material layer 30 may cover the upper surface 10s of the structure 10, and may extend from a portion covering the upper surface 10s of the structure 10 to cover the upper portion of the opening 15 while growing in the transverse direction D1 and the longitudinal direction D2.

The at least one two-dimensional material layer 30 may extend from a portion covering the upper surface 10s of the structure 10 to cover the upper portion of the opening 15 while growing in the transverse direction D1 and the longitudinal direction D2, but may not cover a sidewall of the opening 15. Therefore, the at least one two-dimensional material layer 30 may cover the upper portion of the opening 15, without substantially reducing a volume of the opening 15.

Therefore, according to the above-described embodiments, a volume of the air-gap 20 that may be formed in the opening 15 and of which upper portion is defined by the at least one two-dimensional material layer 30 may be secured as much as possible (i.e., the volume of the air-gap 20 may be maximized by preventing the at least one two-dimensional material layer 30 from forming on the sidewall of the opening 15). In this manner, since the volume of the air-gap 20 may be secured as much as possible, parasitic capacitance between portions of the structure 10 spaced apart by the air-gap 20 may be minimized. Therefore, RC delay of the semiconductor device 1 may be improved, and electrical performance of the semiconductor device 1 may be improved.

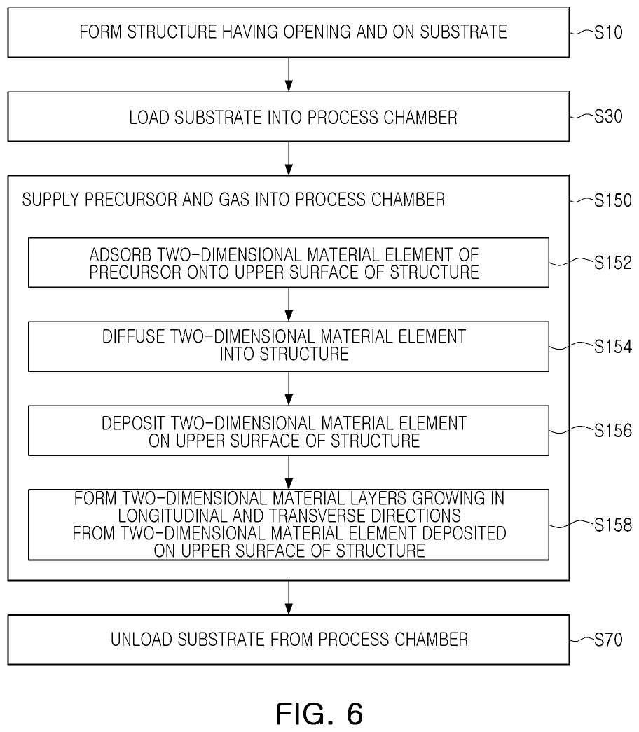

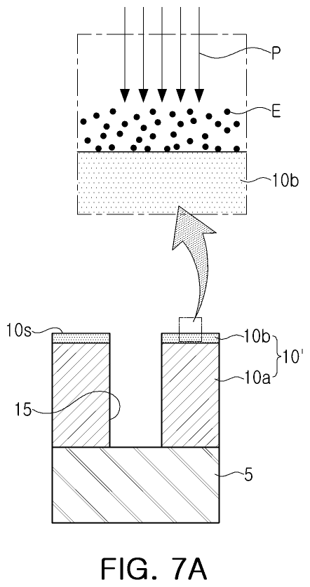

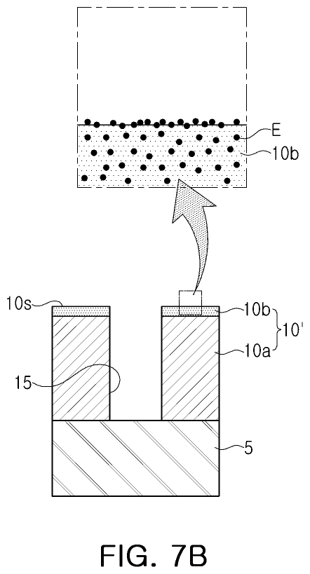

Next, an example of a method of forming the at least one two-dimensional material layer 30, described with reference to FIGS. 1 to 5, will be described with reference to FIGS. 6 and 7A to 7D. In FIGS. 6 and 7A to 7D, FIG. 6 is a flowchart conceptually illustrating a method of fabricating a semiconductor device according to an embodiment of the present inventive concept, and FIGS. 7A to 7C are cross-sectional views conceptually illustrating an example of a method of fabricating a semiconductor device according to an embodiment of the present inventive concept, and FIG. 7D is a top view conceptually illustrating a two-dimensional material layer fabricated according to a method of fabricating a semiconductor device according to an embodiment of the present inventive concept.

Referring to FIGS. 6 and 7A, a structure 10′ having an opening 15 may be formed on a substrate 5 (S10).

In an example, at least, an upper region of the structure 10′ may be formed as a catalyst layer 10b. For example, the structure 10′ may include a lower layer 10a and the catalyst layer 10b on the lower layer 10a.

The catalyst layer 10b may include at least one of Ti, Cu, Ru, Pt, Ir, Ni, or Co.

The substrate 5 may be loaded into a process chamber (e.g., 55 in FIG. 3) (S30). The substrate 5 may be a substrate on which the structure 10′ having the opening 15 is formed.

A precursor and a gas may be supplied to the process chamber (e.g., 55 of FIG. 3) (S150). The precursor P may include an element E of a two-dimensional material. For example, when the two-dimensional material is graphene, the precursor P may include a C element. For example, the precursor P may be a carbon precursor such as CₓH_{y} or the like. For example, the carbon precursor may be C₂H₄ or CH₄.

The gas may include at least one of H₂, N₂, or Ar. The gas may be a mixed gas that may be supplied to the process chamber (e.g., 55 in FIG. 3), together with the precursor P.

The two-dimensional material element E of the precursor P may be adsorbed onto an upper surface 10s of the structure 10′ (S152). For example, when the precursor P is CH₄ (g), the CH₄ (g) may be decomposed into C (s) and a byproduct (g), and the C (s) may be adsorbed onto the upper surface 10s of the structure 10′. In this case, the C (s) may be the two-dimensional material element E.

Referring to FIGS. 6 and 7B, the two-dimensional material element E may diffuse into the structure 10′ (S154). For example, the two-dimensional material element E may diffuse into the catalyst layer 10b of the structure 10′.

Referring to FIGS. 6 and 7C, the two-dimensional material element E may be deposited on the upper surface 10s of the structure 10′ (S156).

Referring to FIGS. 6 and 7D, together with FIGS. 4 and 5, the two-dimensional material element E deposited on the upper surface 10s of the structure 10′ may form two-dimensional material layers (e.g., 30 in FIGS. 4 and 5) growing in the longitudinal and transverse directions from the two-dimensional material element E (S158). The two-dimensional material element E deposited on the upper surface 10s of the structure 10′ may form a nucleus through nucleation, and the two-dimensional material layers (e.g., 30 in FIGS. 4 and 5) may be formed by growing in the longitudinal and transverse directions from the nucleus formed of the two-dimensional material element E. When a two-dimensional material layer among the two-dimensional material layers (e.g., 30 in FIGS. 4 and 5) is graphene, the two-dimensional material layer may have a honeycomb shape, as in FIG. 7D.

Subsequently, the substrate may be unloaded from the process chamber (S70).

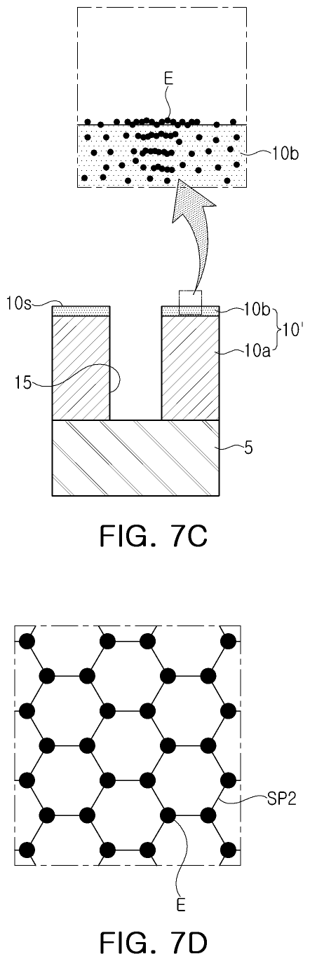

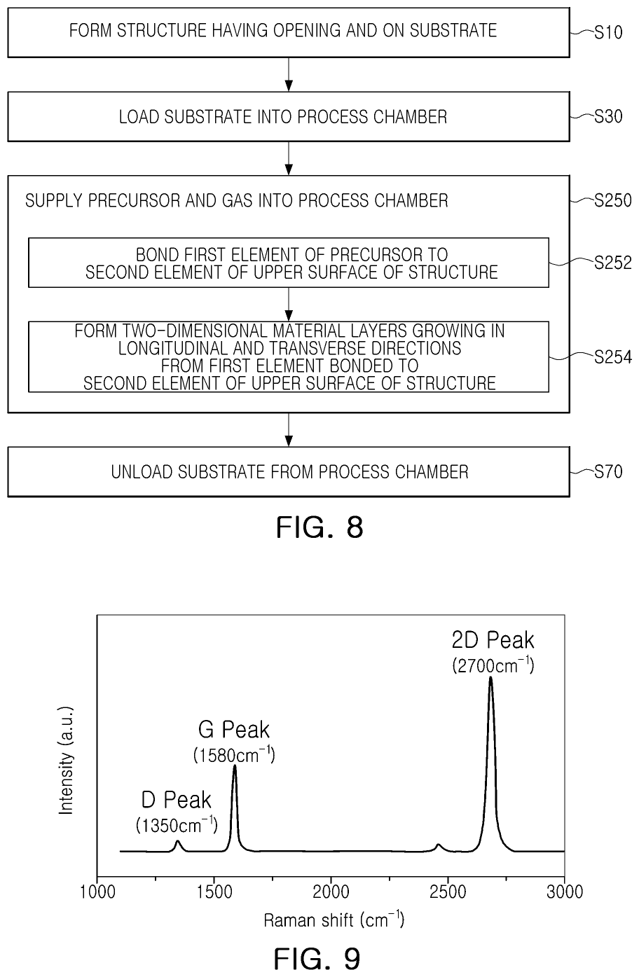

Next, another example of a method of fabricating a semiconductor device including the at least one two-dimensional material layer 30, described with reference to FIGS. 1 to 5, will be described with reference to FIG. 8. FIG. 8 is a flowchart conceptually illustrating another example of a method of fabricating a semiconductor device according to an embodiment of the present inventive concept.

Referring to FIG. 8, together with FIGS. 1 to 5, forming a structure 10 having an opening 15 on a substrate 5 (S10), and loading the substrate 5 into a process chamber (e.g., 55 of FIG. 3) (S30) may be sequentially performed, as described with reference to FIGS. 1 to 5.

At least, an upper surface of the structure 10 may be formed of a non-catalytic material. The structure 10 may include a non-catalytic material, for example, at least one of single crystal silicon, polysilicon, doped silicon, SiOₓ, SiC, SiGe, or SiN.

A precursor and a gas may be supplied to the process chamber (e.g., 55 of FIG. 3) (S250).

A first element of the precursor may be bonded to a second element of the upper surface 10s of the structure 10 (S252). For example, the first element may be an element of a two-dimensional material. The second element of the structure 10 may be an element capable of bonding to the first element, for example, a Si element. For example, on the structure 10, a Si—C covalent bond may be formed between the second element of the structure 10, for example, a Si element, and the first element of the precursor, for example, a C element.

Two-dimensional material layers (e.g., 30 in FIGS. 4 and 5) growing in the longitudinal and transverse directions may be formed from the first element bonded to the second element of the upper surface 10s of the structure 10 (S254). The first element bonded to the second element of the upper surface 10s of the structure 10 may form a nucleus through nucleation, and the two-dimensional material layers (e.g., 30 in FIGS. 4 and 5) may be formed by growing from such a nucleus in the longitudinal and transverse directions.

Subsequently, the substrate may be unloaded from the process chamber (S70).

Next, a material analysis of the at least one two-dimensional material layer (30 of FIGS. 4 and 5) will be described with reference to FIG. 9. FIG. 9 is a graph illustrating a result of analyzing a two-dimensional material layer by Raman spectroscopy.

Referring to FIG. 9, in Raman Spectroscopy, phonons scattered and emitted by transmitting a laser at the at least one two-dimensional material layer (30 of FIGS. 4 and 5) may have their own peaks. A defect, crystallinity, and the number of layers of the at least one two-dimensional material layer (30 of FIGS. 4 and 5) may be elucidated by using such peaks. The at least one two-dimensional material layer (30 of FIGS. 4 and 5) may be graphene.

In an example, in the at least one two-dimensional material layer (30 of FIGS. 4 and 5), D/G may be about 1.0 to 5.0. In this case, D may represent intensity of a D peak, and G may represent intensity of a G peak.

In an example, in the at least one two-dimensional material layer (30 of FIGS. 4 and 5), D/G may be about 1.0 to 3.5.

In an example, in the at least one two-dimensional material layer (30 of FIGS. 4 and 5), 2D/G may be about 0.1 to about 2. In this case, 2D may represent intensity of a 2D peak, and G may represent intensity of a G peak.

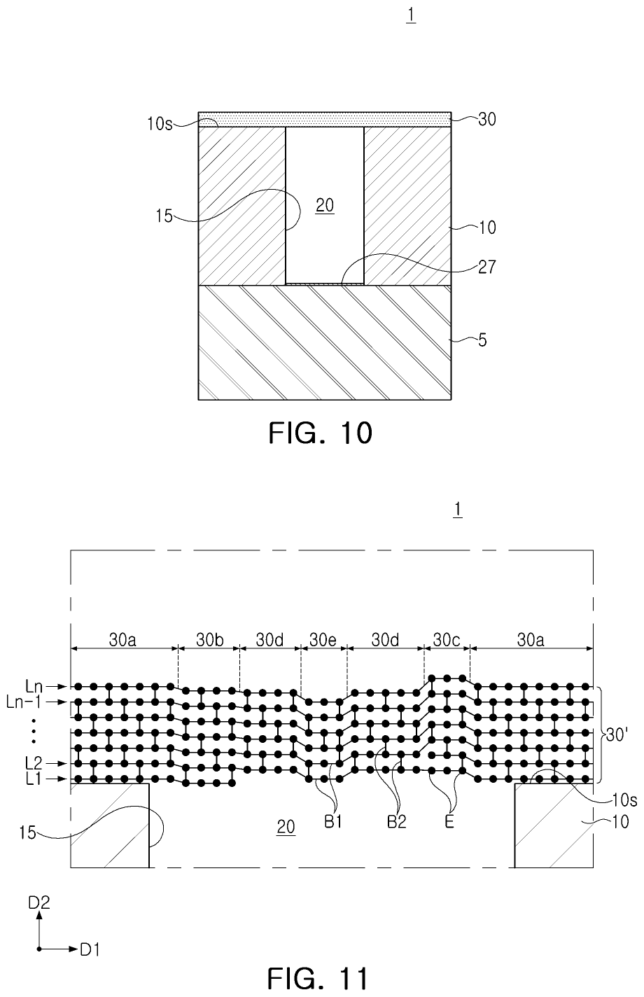

FIG. 10 is a conceptual cross-sectional view illustrating another example of a semiconductor device fabricated according to a method of fabricating a semiconductor device according to an embodiment of the present inventive concept.

Referring to FIG. 10, a semiconductor device 1 according to an embodiment may further include a region 27 including a two-dimensional material element formed on a bottom surface of an opening 15.

Referring to FIGS. 1 to 10, at least one two-dimensional material layer 30 may have a substantially constant thickness, a substantially planar upper surface, and a substantially planar lower surface, although embodiments of the present inventive concept are not limited thereto. For example, the at least one two-dimensional material layer 30 may be deformed into a two-dimensional material layer 30′ having a non-constant thickness, a non-planar upper surface, or a non-planar lower surface, depending on a position. An example of the deformed two-dimensional material layer 30′ will be described with reference to FIG. 11. FIG. 11 is a partially enlarged cross-sectional view corresponding to FIG. 5, and may conceptually represent an example of the deformed two-dimensional material layer 30′. Hereinafter, with reference to FIG. 11, a deformed portion of the at least one two-dimensional material layer 30, described with reference to FIG. 5, will be described.

In a modified example, referring to FIG. 11, at least one two-dimensional material layer 30′ may be formed as a plurality of two-dimensional material layers.

The plurality of two-dimensional material layers 30′ may include regions having different thicknesses. For example, the plurality of two-dimensional material layers 30′ may include regions 30a, 30b, and 30c having a first thickness, and regions 30d and 30e having a second thickness, thinner than the first thickness.

In the plurality of two-dimensional material layers 30′, the regions 30a, 30b, and 30c having the first thickness may be regions in which n two-dimensional material layers L are stacked, and the regions 30d and 30e having the second thickness may be regions in which m two-dimensional material layers L are stacked, where m is smaller than n. In this case, n may be greater than or equal to 3 and less than or equal to 30, and m may be greater than or equal to 2 and less than or equal to 29.

In the plurality of two-dimensional material layers 30′, at least a portion of the regions 30a, 30b, and 30c having the first thickness may overlap an upper surface 10s of a structure 10.

In the plurality of two-dimensional material layers 30′, a portion of the regions 30a, 30b, and 30c having the first thickness may overlap the upper surface 10s of the structure 10, and a remaining portion thereof may overlap an air-gap 20.

The regions 30a, 30b, and 30c having the first thickness in the plurality of two-dimensional material layers 30′ may include a region 30a having an upper surface at a first height level, and a region 30b having an upper surface at a height level, lower than the first height level.

The regions 30a, 30b, and 30c having the first thickness in the plurality of two-dimensional material layers 30′ may include a region 30a having an upper surface at a first height level, and a region 30c having an upper surface at a height level, higher than the first height level.

The regions 30a, 30b, and 30c having the first thickness in the plurality of two-dimensional material layers 30′ may include a region 30a having an upper surface at a first height level, a region 30b having an upper surface at a height level, lower than the first height level, and a region 30c having an upper surface at a height level, higher than the first height level.

The regions 30a, 30b, and 30c having the first thickness in the plurality of two-dimensional material layers 30′ may include a region 30a having a lower surface at a second height level, a region 30b having a lower surface at a height level, lower than the second height level, and a region 30c having a lower surface at a height level, higher than the second height level.

In the regions 30a, 30b, and 30c having the first thickness in the plurality of two-dimensional material layers 30′, the region 30a having a lower surface of a second height level may be in contact with the upper surface 10s of the structure 10.

The regions 30d and 30e having the second thickness in the plurality of two-dimensional material layers 30′ may include a region 30d having an upper surface of a third height level, and a region 30e having an upper surface at a height level, lower than the third height level.

The regions 30d and 30e having the second thickness in the plurality of two-dimensional material layers 30′ may include a region 30d having a lower surface of a fourth height level, and a region 30e having a lower surface at a height level, lower than the fourth height level.

At least one of the upper surfaces of the regions 30d and 30e having the second thickness in the plurality of two-dimensional material layers 30′ may be disposed at a height level, lower than at least one of upper surfaces of the regions 30a, 30b, and 30c having the first thickness in the plurality of two-dimensional material layers 30′.

At least one of the lower surfaces of the regions 30d and 30e having the second thickness in the plurality of two-dimensional material layers 30′ may be disposed at a height level, higher than at least one of lower surfaces of the regions 30a, 30b, and 30c having the first thickness in the plurality of two-dimensional material layers 30′.

As described above, in FIGS. 1 to 11, the upper portion of the air-gap 20 may be defined by the at least one two-dimensional material layer 30 or 30′ having conductivity, but embodiments of the present inventive concept are not limited thereto. Hereinafter, examples of forming a non-conductive material layer and examples of converting the at least one two-dimensional material layer 30 or 30′ having conductivity into those having non-conductivity will be described.

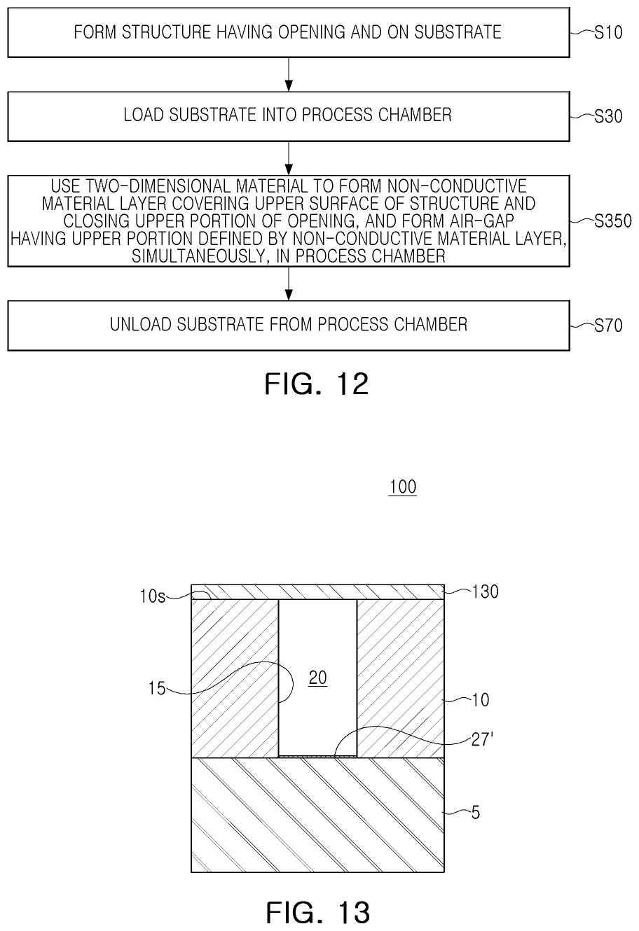

First, another example of a method of fabricating a semiconductor device according to an embodiment of the present inventive concept will be described with reference to FIGS. 12 and 13. FIG. 12 is a flowchart conceptually illustrating another example of a method of fabricating a semiconductor device according to an embodiment of the present inventive concept, and FIG. 13 is a cross-sectional view illustrating an example of a semiconductor device fabricated according to another example of a method of fabricating a semiconductor device according to an embodiment of the present inventive concept.

Referring to FIG. 12, forming a structure 10 having an opening 15 and on a substrate 5 (S10), and loading the substrate 5 into a process chamber (e.g., 55 of FIG. 3) (S30) may be sequentially performed, as described with reference to FIGS. 1 to 5.

In the process chamber (e.g., 55 in FIG. 3), a two-dimensional material capable of forming a two-dimensional material layer may be used to form a non-conductive material layer 130 covering an upper surface 10s of the structure 10 and closing an upper portion of the opening 15, and form an air-gap 20 having an upper portion defined by the non-conductive material layer 130, simultaneously (S350).

The two-dimensional material may include at least one of a carbon material, a transition metal dichalcogenide (TMD) material, a black phosphorous material, or a hexagonal boron-nitride (hBN) material, which may form a two-dimensional material layer.

In an example, a region 27 including a two-dimensional material element formed on a bottom surface of the opening 15 may be formed.

The substrate 5 may be unloaded from the process chamber (e.g., 55 of FIG. 3) (S70).

Therefore, a semiconductor device 100 including the structure 10 having the opening 15 on the substrate 5, and the non-conductive material layer 130 disposed on the upper surface 10s of the structure 10 and defining the upper portion of the air-gap 20 may be provided.

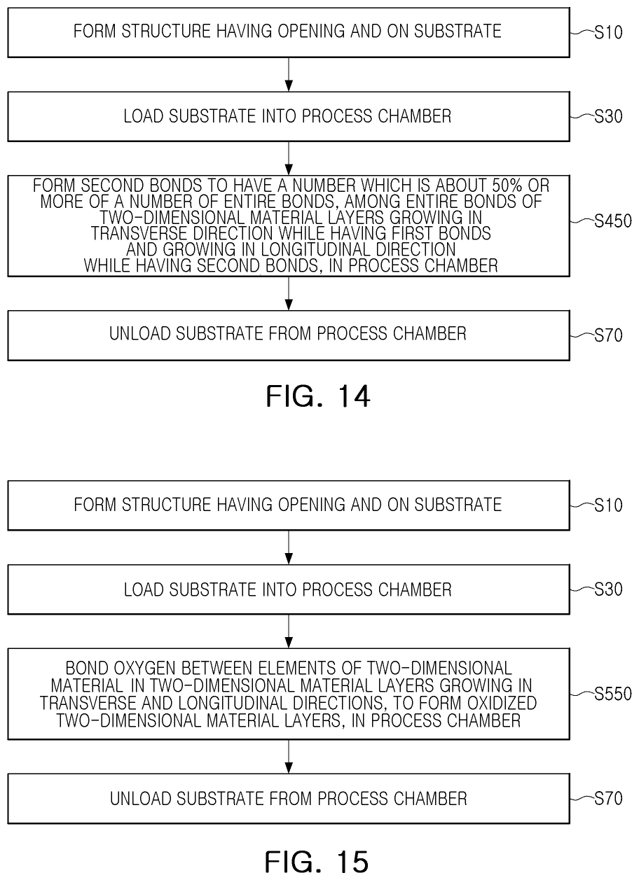

Next, an example method of forming the non-conductive material layer 130 of FIG. 13 will be described with reference to FIG. 14. FIG. 14 is a flowchart illustrating an example of a method of forming a non-conductive material layer (e.g., 130 of FIG. 13).

Referring to FIGS. 13 and 14, forming a structure 10 having an opening 15 on a substrate 5 (S10), and loading the substrate 5 into a process chamber (e.g., 55 of FIG. 3) (S30) may be sequentially performed, as described with reference to FIGS. 1 to 5.

In the process chamber (e.g., 55 in FIG. 3), among entire bonds of two-dimensional material layers growing in the transverse direction while having first bonds and growing in the longitudinal direction while having second bonds, the second bonds may be formed to have a number which is about 50% or more of a number of the entire bonds (S450). For example, when the two-dimensional material layers are the two-dimensional material layers described with reference to FIGS. 5 and 11 (30 of FIGS. 5 and 30′ of FIG. 11), the first bonds B1 may be SP2 bonds, and the second bonds B2 may be SP3 bonds. The number of the second bonds B2 may be greater than the number of the first bonds B1. A non-conductive material layer 130 may be formed by forming two-dimensional material layers growing in the transverse direction while having first bonds in the transverse direction and growing in the longitudinal direction while having second bonds in the longitudinal direction, and increasing the number of the second bonds to amorphize the two-dimensional material layers.

As the number of the second bond B2 increases, amorphization of the two-dimensional material layers (30 of FIGS. 5 and 30′ of FIG. 11) may be induced by an irregular arrangement of elements of the two-dimensional material layers (30 of FIGS. 5 and 30′ of FIG. 11), for example, a two-dimensional material element E (e.g., carbon elements E), to form the non-conductive material layer 130. At least a portion of the non-conductive material layer 130 may be amorphous.

The substrate 5 may be unloaded from the process chamber (e.g., 55 of FIG. 3) (S70).

Next, another example of a method of forming the non-conductive material layer 130 of FIG. 13 will be described with reference to FIG. 15. FIG. 15 is a flowchart illustrating another example of a method of forming a non-conductive material layer (e.g., 130 of FIG. 13).

Referring to FIGS. 13 and 15, forming a structure 10 having an opening 15 on a substrate 5 (S10), and loading the substrate 5 into a process chamber (e.g., 55 of FIG. 3) (S30) may be sequentially performed, as described with reference to FIGS. 1 to 5.

In the process chamber (e.g., 55 of FIG. 3), oxygen may be bonded between elements of a two-dimensional material in two-dimensional material layers growing in the transverse and longitudinal directions, to form oxidized two-dimensional material layers (S550). In this case, the oxidized two-dimensional material layers may be non-conductive material layers (e.g., 130 of FIG. 13). For example, oxygen may be interposed between carbon bonds to form one graphene oxide layer. Then, one or more graphene oxide layers may be provided on the one graphene oxide layer to form a non-conductive material layer (e.g., 130 of FIG. 13).

In an embodiment, a graphene oxide layer is illustrated as an example of the oxidized two-dimensional material layer, but the embodiment of the present inventive concept is not limited thereto. For example, the oxidized two-dimensional material layer may be an oxide material layer of a transition metal dichalcogenide (TMD) material layer, a black phosphorous material layer, or a hexagonal boron-nitride (hBN) material layer.

The substrate 5 may be unloaded from the process chamber (e.g., 55 of FIG. 3) (S70).

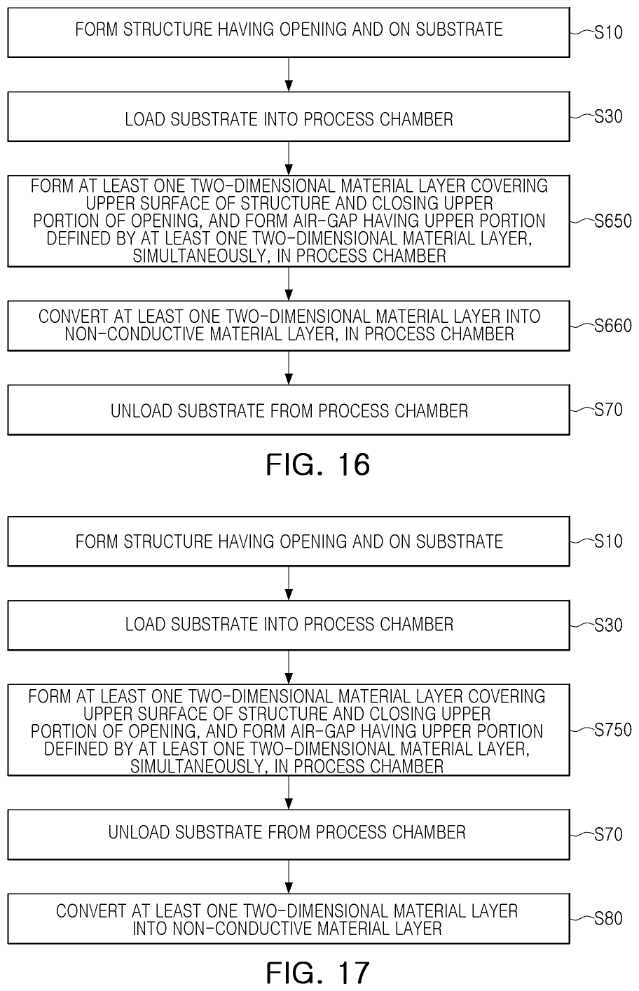

Next, another example of a method of forming the non-conductive material layer 130 of FIG. 13 will be described with reference to FIG. 16. FIG. 16 is a flowchart illustrating another example of a method of forming a non-conductive material layer (e.g., 130 of FIG. 13).

Referring to FIGS. 13 and 16, forming a structure 10 having an opening 15 on a substrate 5 (S10), and loading the substrate 5 into a process chamber (e.g., 55 of FIG. 3) (S30) may be sequentially performed, as described with reference to FIGS. 1 to 5.

In the process chamber (e.g., 55 in FIG. 3), at least one two-dimensional material layer covering an upper surface 10s of the structure 10 and closing an upper portion of the opening 15 may be formed, and an air-gap 20 having an upper portion defined by the at least one two-dimensional material layer may be formed, simultaneously (S650).

The at least one two-dimensional material layer may be at least one two-dimensional material layer (30 of FIGS. 4, 5, and 10, and 30′ of FIG. 11) formed according to the embodiments described with reference to FIGS. 1 to 8, 10, and 11.

In the process chamber (e.g., 55 of FIG. 3), the at least one two-dimensional material layer (e.g., 30 of FIGS. 4, 5 and 10, and 30′ of FIG. 11) may be converted into a non-conductive material layer (S660). Therefore, a non-conductive material layer 130, as described with reference to FIG. 13, may be formed.

In an example, converting the at least one two-dimensional material layer (e.g., 30 of FIGS. 4, 5 and 10, and 30′ of FIG. 11) to a non-conductive material layer may include oxidizing the at least one two-dimensional material layer (e.g., 30 of FIGS. 4, 5 and 10, and 30′ of FIG. 11) to form an oxidized two-dimensional material layer. In another example, converting the at least one two-dimensional material layer (e.g., 30 of FIGS. 4, 5 and 10, and 30′ of FIG. 11) to a non-conductive material layer may include inducing amorphization of the at least one two-dimensional material layer (e.g., 30 of FIGS. 4, 5 and 10, and 30′ of FIG. 11).

The substrate 5 may be unloaded from the process chamber (e.g., 55 of FIG. 3) (S70).

Next, another example of a method of forming the non-conductive material layer 130 of FIG. 13 will be described with reference to FIG. 17. FIG. 17 is a flowchart illustrating another example of a method of forming a non-conductive material layer (e.g., 130 of FIG. 13).

Referring to FIGS. 13 and 17, forming a structure 10 having an opening 15 on a substrate 5 (S10), and loading the substrate 5 into a process chamber (e.g., 55 of FIG. 3) (S30) may be sequentially performed, as described with reference to FIGS. 1 to 5.

In the process chamber (e.g., 55 in FIG. 3), at least one two-dimensional material layer covering an upper surface 10s of the structure 10 and closing an upper portion of the opening 15 may be formed, and an air-gap 20 having an upper portion defined by the at least one two-dimensional material layer may be formed, simultaneously (S750).

The at least one two-dimensional material layer may be at least one two-dimensional material layer (30 of FIGS. 4, 5, and 10, and 30′ of FIG. 11) formed according to the embodiments described with reference to FIGS. 1 to 8, 10, and 11.

The substrate 5 may be unloaded from the process chamber (e.g., 55 of FIG. 3) (S70).

Subsequently, the at least one two-dimensional material layer (30 of FIGS. 4, 5 and 10, and 30′ of FIG. 11) may be converted into a non-conductive material layer (S80). Therefore, a non-conductive material layer 130, as described with reference to FIG. 13, may be formed.

In an example, converting the at least one two-dimensional material layer (e.g., 30 of FIGS. 4, 5 and 10, and 30′ of FIG. 11) to a non-conductive material layer may include oxidizing the at least one two-dimensional material layer (e.g., 30 of FIGS. 4, 5 and 10, and 30′ of FIG. 11) to form an oxidized two-dimensional material layer. In another example, converting the at least one two-dimensional material layer (e.g., 30 of FIGS. 4, 5 and 10, and 30′ of FIG. 11) to a non-conductive material layer may include inducing amorphization of the at least one two-dimensional material layer (e.g., 30 of FIGS. 4, 5 and 10, and 30′ of FIG. 11).

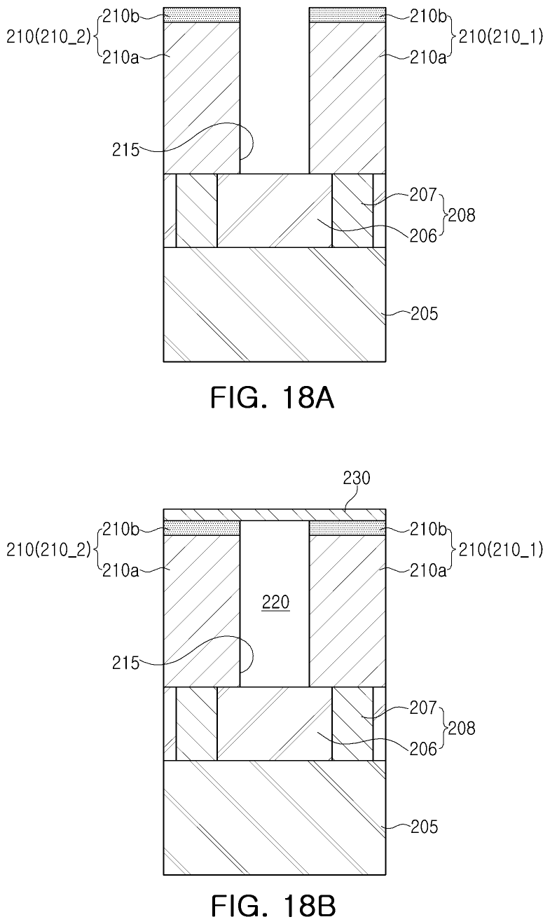

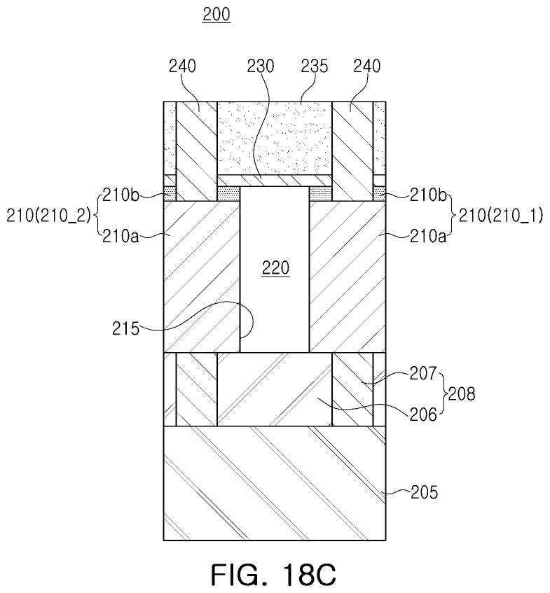

Next, a method of fabricating a semiconductor device using a non-conductive material layer 130, as illustrated in FIG. 13, and the semiconductor device fabricated according to the method will be described with reference to FIGS. 18A to 18C. FIGS. 18A to 18C are cross-sectional views conceptually illustrating a method of fabricating a semiconductor device using a non-conductive material layer 130, and the semiconductor device fabricated according to the method.

Referring to FIG. 18A, a lower structure 208 may be formed on a substrate 205. The substrate 205 may include a semiconductor substrate. The lower structure 208 may include a lower insulating layer 206 and a lower conductive region 207. The lower conductive region 207 may be a contact plug or a conductive via.

A structure 210 having an opening 215 may be formed on the lower structure 208.

In an example, the structure 210 may be formed of a conductive material. For example, the structure 210 may include at least one of W, Mo, Al, Ta, Ti, Cu, Ru, Pt, Ir, Ni, Co, TiN, TaN, WN, WCN, or doped silicon, but embodiments are not limited thereto, and other materials having conductivity may be included.

In an example, at least a portion of the structure 210 may include a catalyst layer 210b. For example, the structure 210 may include a lower conductive layer 210a and the catalyst layer 210b on the lower conductive layer 210a. The catalyst layer 210b may include at least one of Ti, Cu, Ru, Pt, Ir, Ni, or Co.

In an example, the structure 210 may include a first conductive pattern 210_1 and a second conductive pattern 210_2, spaced apart from each other. The opening 215 may be formed between the first conductive pattern 210_1 and the second conductive pattern 210_2. The first conductive pattern 210_1 and the second conductive pattern 210_2 may be conductive wirings.

Referring to FIG. 18B, a non-conductive material layer 230 for closing an upper portion of the opening 215 may be formed on the structure 210. An air-gap 220 may be formed in the opening 215 by the non-conductive material layer 230.

The non-conductive material layer 230 may be formed according to any one of the embodiments described with reference to FIGS. 12 to 17. For example, the non-conductive material layer 230 may be formed in substantially the same manner as the non-conductive material layer 130 described with reference to FIG. 13.

Referring to FIG. 18C, an upper insulating layer 235 may be formed on the non-conductive material layer 230. Upper contact plugs 240 passing through the upper insulating layer 235 and the non-conductive material layer 230 and electrically connected to the structure 210 may be formed.

A semiconductor device 200 formed according to the method described with reference to FIGS. 18A to 18C may be provided. The semiconductor device 200 may include the substrate 205, the lower structure 208, the structure 210 having the opening 215, the non-conductive material layer 230 covering an upper surface of the structure 210 and defining an upper portion of the air-gap 220, the upper insulating layer 235, and the upper contact plugs 240.

According to an embodiment, the non-conductive material layer 230 may cover the upper surface of the structure 210, and may be formed using at least one two-dimensional material layer extending to cover the upper portion of the opening 215 while growing in the transverse and longitudinal directions from a portion covering the upper surface of the structure 210. The non-conductive material layer 230 may extend to cover the upper portion of the opening 215 while growing in the transverse and longitudinal directions from the portion covering the upper surface of the structure 210, but may not cover a sidewall of the opening 215. Therefore, the non-conductive material layer 230 may cover the upper portion of the opening 215 without substantially reducing a volume of the opening 215. Therefore, a volume of the air-gap 220 formed in the opening 215 and having the upper portion defined by the non-conductive material layer 230 may be secured as much as possible. In this manner, since the volume of the air-gap 220 may be secured as much as possible, parasitic capacitance between the first and second conductive patterns 210_1 and 210_2 of the structure 210 spaced apart by the air-gap 220 may be minimized. Therefore, RC delay of the semiconductor device 200 may be improved, and electrical performance of the semiconductor device 200 may be improved.

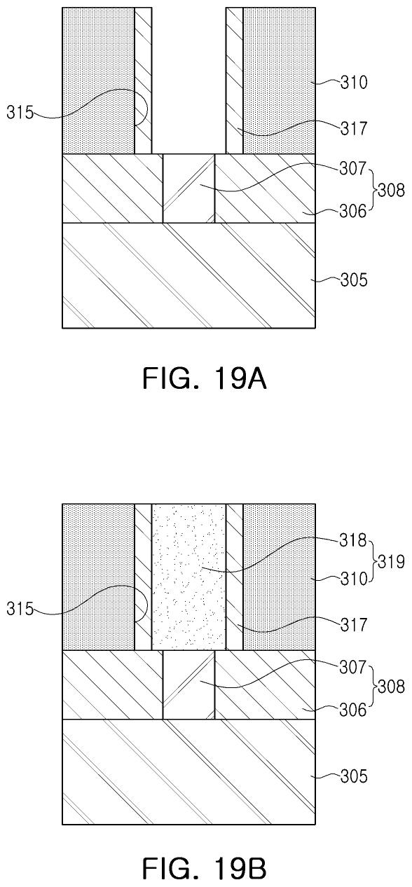

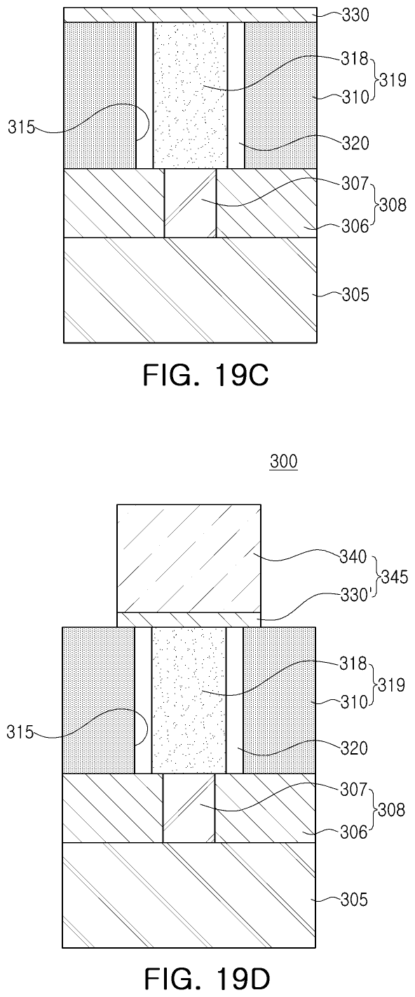

Next, a method of fabricating a semiconductor device using at least one two-dimensional material layer (e.g., 30 of FIGS. 4 and 5 and 30′ of FIG. 11), as in FIGS. 4, 5, and 11, the semiconductor device fabricated according to the method will be described with reference to FIGS. 19A to 19D. FIGS. 19A to 19D are cross-sectional views illustrating a method of fabricating a semiconductor device using at least one two-dimensional material layer (e.g., 30 of FIGS. 4 and 5 and 30′ of FIG. 11) and the semiconductor device fabricated according to the method.

Referring to FIG. 19A, a lower structure 308 may be formed on a substrate 305. The substrate 305 may include a semiconductor substrate. The lower structure 308 may include a lower layer 306 and a lower conductive region 307. The lower layer 306 may include an insulating material layer. The lower conductive region 307 may be at least one of a source/drain region, a contact plug, or a metal line.

A structure 310 having an opening 315 may be formed on the lower structure 308. The structure 310 may include at least one of an insulating material and a conductive material.

In an example, the structure 310 may be formed as an insulating material layer.

In another example, the structure 310 may include a conductive pattern, and an insulating material layer covering side and upper surfaces of the conductive pattern.

A sacrificial spacer 317 may be formed on an inner wall of the opening 315.

Referring to FIG. 19B, a structure 318 filling the opening 315 in which the sacrificial spacer 317 is formed may be formed on an inner wall. The structure 318 may be a conductive pattern. For example, the structure 318 may be a conductive contact plug.

The structure 310 may be referred to as a first pattern, and the structure 318 may be referred to as a second pattern.

Hereinafter, the structure 310 will be described as a first pattern, and the structure 318 will be described as a second pattern. In addition, the first pattern 310 and the second pattern 318 will be described to constitute a structure 319.

Referring to FIG. 19C, the sacrificial spacer 317 may be removed to form an empty space between the first and second patterns 310 and 318 of the structure 319, and at least one two-dimensional material layer 330 at least covering an upper surface of the second pattern 318 and closing an upper portion of the empty space from which the sacrificial spacer 317 is removed may be formed.

The empty space in which the sacrificial spacer 317 is removed and whose upper portion is covered by the at least one two-dimensional material layer 330 may be defined as an air-gap 320.

The at least one two-dimensional material layer 330 may be formed in substantially the same manner as the method of forming the at least one two-dimensional material layer (e.g., 30 of FIGS. 4 and 5 and 30′ of FIG. 11), as in FIGS. 4, 5, and 11.

Referring to FIG. 19D, after the at least one two-dimensional material layer 330 is formed, a conductive layer may be formed, and the conductive layer and the at least one two-dimensional material layer 330 may be patterned to form an upper conductive pattern 345.

The upper conductive pattern 345 may include at least one two-dimensional material pattern 330′ that remains after patterning the at least one two-dimensional material layer 330, and a conductive pattern 340 that remains after patterning the conductive layer.

When the structure 319 is a conductive contact plug, the at least one two-dimensional material pattern 330′ may reduce resistance between the conductive pattern 340 and the second pattern 318.

In another example, since the conductive pattern 340 may be omitted, the upper conductive pattern 345 may be provided as the at least one two-dimensional material pattern 330′.

A semiconductor device 300 formed according to the method described with reference to FIGS. 19A to 19D may be provided. The semiconductor device 300 may include the substrate 305, the lower structure 308, the structure 319, the air-gap 320, and the upper conductive pattern 345. The upper conductive pattern 345 may include the at least one two-dimensional material pattern 330′.

In an embodiment, the at least one two-dimensional material pattern 330′ may define an upper portion of the air-gap 320 while maximally securing a volume of the air-gap 320.

In an embodiment, when the first pattern 310 of the structure 319 includes a conductive pattern surrounded by an insulating material layer on side and upper surfaces, and the second pattern 318 of the structure 319 is a conductive contact plug, parasitic capacitance between the first pattern 310 and the second pattern 318 may be minimized due to the air-gap 320 capable of securing the volume as much as possible. Therefore, RC delay of the structure 319 may be improved.

According to embodiments of the inventive concept, a method of fabricating a semiconductor device including a two-dimensional material layer defining an air-gap, and the semiconductor device fabricated thereby may be provided. The two-dimensional material layer may cover an upper surface of a structure having an opening on the structure and may close an upper portion of the opening, to define an upper portion of the air-gap formed in the opening.

The two-dimensional material layer may be formed on the upper surface of the structure to close the upper portion of the opening while growing in transverse and longitudinal directions. Therefore, since the two-dimensional material layer may cover the upper portion of the opening without substantially reducing a volume of the opening, a volume of the air-gap formed in the opening and having the upper portion defined by the two-dimensional material layer may be secured as much as possible. Therefore, when the structure includes conductive patterns spaced apart from each other, the air-gap may minimize parasitic capacitance between the conductive patterns to improve RC delay. Therefore, electrical performance of the semiconductor device may be improved.

Various advantages and effects of the present inventive concept are not limited to the above, and will be more easily understood in the process of describing specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A method of fabricating a semiconductor device, the method comprising:
forming a structure on a substrate, wherein the structure comprises an opening;
loading the substrate into a process chamber;
forming at least one two-dimensional material layer on an upper surface of the structure so as to overlie the opening and form an air-gap, wherein an upper portion of the air-gap is defined by the at least one two-dimensional material layer; and
unloading the substrate from the process chamber.

2. The method of claim 1, wherein the at least one two-dimensional material layer comprises a plurality of two-dimensional material layers, and
wherein the plurality of two-dimensional material layers are formed by growing a two-dimensional material in transverse and longitudinal directions on the upper surface of the structure.

3. The method of claim 2, wherein a growth rate of the two-dimensional material in the transverse direction is higher than a growth rate of the two-dimensional material in the longitudinal direction.

4. The method of claim 2, wherein a growth rate of the two-dimensional material in the transverse direction is about 2 to about 100 times higher than a growth rate of the two-dimensional material in the longitudinal direction.

5. The method of claim 1, wherein a thickness of the at least one two-dimensional material layer is about 3 Å to about 100 Å.

6. The method of claim 1, wherein a width of the opening is about 1 nm to about 1 μm.

7. The method of claim 1, wherein the at least one two-dimensional material layer comprises between 2 and 30 two-dimensional material layers.

8. The method of claim 1, wherein the at least one two-dimensional material layer comprises a carbon material layer, a transition metal dichalcogenide (TMD) material layer, a black phosphorous material layer, or a hexagonal boron-nitride (hBN) material layer.

9. The method of claim 1, wherein the at least one two-dimensional material layer is conductive, and
the method further comprising converting the at least one two-dimensional material layer to be non-conductive before the unloading the substrate from the process chamber.

10. The method of claim 9, wherein the converting the at least one two-dimensional material layer to be non-conductive comprises inducing amorphization of the at least one two-dimensional material layer.

11. The method of claim 9, wherein the converting the at least one two-dimensional material layer to be non-conductive comprises oxidizing the at least one two-dimensional material layer.

12. The method of claim 11, wherein the non-conductive material layer comprises a plurality of layers of graphene oxide.

13. The method of claim 1, wherein the at least one two-dimensional material layer is conductive, and
the method further comprising converting the at least one two-dimensional material layer to be non-conductive after the unloading the substrate from the process chamber.

14. A method of fabricating a semiconductor device, the method comprising:
forming a structure on a substrate, wherein the structure comprises an opening; and
forming at least one two-dimensional material layer on an upper surface of the structure so as to overlie the opening and form an air-gap.

15. The method of claim 14, wherein the at least one two-dimensional material layer is not on a sidewall of the opening.

16. The method of claim 14, wherein the at least one two-dimensional material layer comprises a plurality of two-dimensional material layers, and
wherein the plurality of two-dimensional material layers have a first thickness on the upper surface of the structure, and a second thickness, less than the first thickness, above the air-gap.

17. The method of claim 14, wherein the at least one two-dimensional material layer comprises a plurality of two-dimensional material layers, and
wherein the plurality of two-dimensional material layers comprise an upper surface at a first level above the structure, and an upper surface at a second level above the air-gap, wherein the second level is different from the first level.

18. A method of fabricating a semiconductor device, the method comprising:
forming a structure on a substrate, wherein the structure comprises an opening; and
forming a non-conductive material layer using at least one two-dimensional material layer,
wherein the non-conductive material layer is on an upper surface of the structure so as to overlie the opening and form an air-gap, and
wherein an upper portion of the air-gap is defined by the non-conductive material layer.

19. The method of claim 18, wherein the forming the non-conductive material layer comprises forming a plurality of two-dimensional material layers such that an irregular arrangement of elements of the plurality of two-dimensional material layers is induced.

20. The method of claim 18, wherein the forming the non-conductive material layer comprises oxidizing the at least one two-dimensional material layer.
